(19) United States
(12) Patent Application Publication
(10) Pub. No.: US 2008/0251125 A1
(43) Pub. Date: Oct. 16, 2008

(54) PHOTOELECTRIC CONVERSION STRUCTURE AND TEMPERATURE CONTROL SYSTEM USING THE SAME

(75) Inventors: Ching-Fu Cheng, Taipei (TW); Hsiang-Jui Hung, Taipei (TW); Sun-Chen Yang, Taipei (TW); Yun-Jiun You, Taipei (TW); Chun-San Lin, Taipei (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: ASUSTeK COMPUTER INC., Taipei (TW)

(21) Appl. No.: 12/103,718

(22) Filed: Apr. 16, 2008

(30) Foreign Application Priority Data
Apr. 16, 2007 (TW) 96113304

(51) Int. Cl. H01L 31/052; F25B 21/02

(52) U.S. Cl. 136/259; 62/3.2; 257/E31.131

(57) ABSTRACT

A photoelectric conversion structure includes a light energy plate, a thermoelectric cooling element and a control circuit. The light energy plate is suitable to receive light energy and convert the light energy to electrical energy. The thermoelectric cooling element has a hot side and a cold side. The hot side faces the light energy plate. The control circuit is electrically connected to the light energy plate and the thermoelectric cooling element. The control circuit is suitable to provide the electrical energy for the thermoelectric cooling element.

### CROSS-REFERENCE TO RELATED APPLICATION

This application claims the priority benefit of Taiwan application serial no. 96113304, filed on Apr. 16, 2007. The entirety the above-mentioned patent application is hereby incorporated by reference herein and made a part of specification.

### BACKGROUND OF THE INVENTION

1. Field of the Invention

The invention relates to a photoelectric conversion structure and a temperature control system using the same and, more particularly, to a temperature control system using renewable energy.

2. Description of the Related Art

Along with the rapid development of the science and technology, energy of the earth is rapidly and overly developed, and then the present energy shortage condition is very serious, and the environment is seriously damaged.

For a long time, power is mostly provided by burning material. For example, after the industrial revolution, the usage of a steam engine causes coal mines to be widely exploited. The quantity of surplus coal decreases because of exploitation of the coal mines, and the environment is polluted by burning coal. For the development of the science and technology needs energy which has more economic value and wide applicable fields, petroleum which can be used to produce a plurality of derivatives replaces the coal.

Gas, white oil, diesel oil, heavy oil and residual asphalt can be extracted from the petroleum under different fractional distillation temperature. All fractions of the petroleum have great availability. Although the petroleum has high economic value, it is non-renewable energy and is gradually exhausted along with the exploitation of the petroleum. When objects made from the petroleum burns, since the objects always are mixed with other chemical material, the environment is seriously damaged.

To solve the energy shortage problem and to prevent products of the science and technology and waste derived from the manufacture process of the products from polluting the environment, scientists advocate replacing non-renewable energy with renewable energy, and they want to utilize energy which can be obtained in daily life to achieve the objective of protecting environment and using forever.

### BRIEF SUMMARY OF THE INVENTION

The objective of the invention is to provide a photoelectric conversion structure which utilizes renewable energy as electrical energy, and therefore, an effect of protecting environment is obtained.

Another objective of the invention is to provide a temperature control system which utilizes the above photoelectric conversion structure to control the temperature of closed space.

To achieve the above or other objectives, the invention provides a photoelectric conversion structure which includes a light energy plate, a thermoelectric cooling element and a control circuit. The light energy plate is suitable to receive light energy and convert the light energy to electrical energy. The thermoelectric cooling element has a hot side and a cold side, and the hot side faces the light energy plate. The control circuit is electrically connected to the light energy plate and the thermoelectric cooling element, and the control circuit is suitable to provide the electrical energy for the thermoelectric cooling element.

In one embodiment of the invention, the light energy plate is a solar energy plate.

In one embodiment of the invention, the light energy is visible ray or invisible ray.

In one embodiment of the invention, the control circuit includes a converter and a controller. The converter is electrically connected to the light energy plate and the thermoelectric cooling element, and the controller is electrically connected to the converter.

In one embodiment of the invention, the controller further includes a temperature sensor which is suitable to transmit a sensed temperature signal to the controller.

In one embodiment of the invention, the hot side directly contacts the light energy plate.

The invention further provides a temperature control system which is suitable to adjust the temperature of closed space, and the temperature control system includes a light energy plate, a thermoelectric cooling element and a control circuit. The light energy plate is suitable to receive light energy and convert the light energy to electrical energy. The thermoelectric cooling element has a hot side and a cold side, the hot side faces the light energy plate, and the cold side faces the interior space of the closed space. The control circuit is electrically connected to the light energy plate and the thermoelectric cooling element, and the control circuit is suitable to provide the electrical energy for the thermoelectric cooling element to control the temperature of the interior of the closed space.

In one embodiment of the invention, the light energy plate is a solar energy plate.

In one embodiment of the invention, the light energy is visible ray or invisible ray.

In one embodiment of the invention, the control circuit includes a converter and a controller, and the converter is electrically connected to the controller.

In one embodiment of the invention, the controller further includes a temperature sensor which is suitable to transmit a sensed temperature signal to the controller.

In one embodiment of the invention, the temperature sensor is disposed in the closed space.

In one embodiment of the invention, the temperature control system further includes a storage battery electrically connected to the light energy plate and the control circuit.

In one embodiment of the invention, the temperature control system further includes a heat removal system electrically connected to the thermoelectric cooling element.

In one embodiment of the invention, the hot side directly contacts the light energy plate.

The invention further provides a temperature control system applied to closed space, and the temperature control system includes two light energy plates, at least a thermoelectric cooling element, a control circuit and a shielding cover. The two light energy plates are obliquely provided at the top of the closed space, and a first gap is formed between the two light energy plates. The two light energy plates are suitable to receive light energy and convert the light energy to electrical energy. The thermoelectric cooling element is provided in the closed space and is electrically connected to the two light energy plates. The thermoelectric cooling element has a hot side and a cold side. The hot side faces the light energy plate, and the cold side faces the interior of the closed space. The control circuit is electrically connected to the two light energy plates and the thermoelectric cooling element, and the control circuit is suitable to provide the electrical energy for the thermoelectric cooling element to control the temperature of the interior of the closed space. The shielding cover is located above the first gap between the two light energy plates to shield the first gap, and a distance is formed between the shielding cover and tops of the two light energy plates.

In one embodiment of the invention, the light energy plate is a solar energy plate.

In one embodiment of the invention, the light energy is visible ray or invisible ray.

In one embodiment of the invention, a second gap is formed between the hot side of the thermoelectric cooling element and the light energy plate.

In one embodiment of the invention, the temperature control system further includes a heat removal system provided at the second gap and electrically connected to the thermoelectric cooling element.

In one embodiment of the invention, the temperature control system further includes a storage battery electrically connected to the light energy plate and the control circuit.

In one embodiment of the invention, the control circuit includes a converter and a controller, and the converter is electrically connected to the controller.

In one embodiment of the invention, the controller further includes a temperature sensor which is suitable to transmit a sensed temperature signal to the controller.

In one embodiment of the invention, the temperature sensor is disposed in the closed space.

In one embodiment of the invention, the hot side directly contacts the light energy plate.

In the invention, the light energy plate is utilized to collect the light energy as an electrical energy source of the temperature control system. Since non-renewable energy is not used as electrical energy, and no pollutant is discharged during a power generation process or a temperature control process, the objective of protecting environment is achieved.

In the invention, heat generated by the hot side of the thermoelectric cooling element is used to excite of energy levels of the light energy plate. Since the heated light energy plate allows the energy levels of electrons to increase, the objective of enhancing the conversion efficiency of the light energy plate can be achieved.

These and other features, aspects, and advantages of the present invention will become better understood with regard to the following description, appended claims, and accompanying drawings.

### BRIEF DESCRIPTION OF THE SEVERAL VIEWS OF THE DRAWINGS

FIG. 1 is a block diagram showing a temperature control system according to one embodiment of the invention.

FIG. 2 is a schematic diagram showing a temperature control system which is applied to adjust indoor temperature according to one embodiment of the invention.

FIG. 3 is a block diagram showing a temperature control system having a storage battery.

FIG. 4 is a schematic diagram showing that an airflow path is formed between a thermoelectric cooling element and a light energy plate when a temperature control system is applied to adjust indoor temperature.

### DETAILED DESCRIPTION OF THE EMBODIMENTS

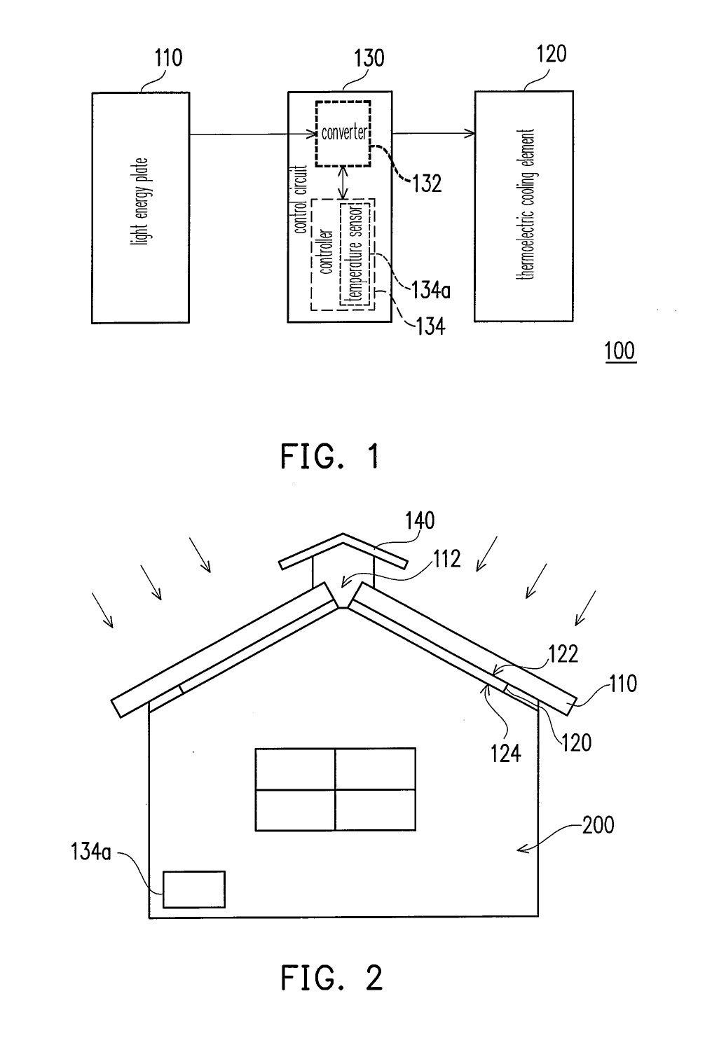

FIG. 1 is a block diagram showing a temperature control system according to one embodiment of the invention. As shown in FIG. 1, a temperature control system 100 of the embodiment of the invention is suitable to control the temperature of closed space. For example, indoor temperature of a house or room or temperature of an object is controlled. The temperature control system 100 includes a light energy plate 110, a thermoelectric cooling element 120 and a control circuit 130. The light energy plate 110 is suitable to receive light energy and convert the light energy to electrical energy. In the embodiment, the above light energy plate 110 may be an ordinary solar energy plate or other devices which can receive light energy and convert the light energy to electrical energy. The light received by the light energy plate 110 may be solar light or light of an indoor lamp, and the light energy includes visible ray and invisible ray such as infrared ray, ultraviolet light, etc. The thermoelectric cooling element 120 is electrically connected to the light energy plate 110 via the control circuit 130, and the hot side of the thermoelectric cooling element 120 faces the object or indoor space which needs to be controlled. The control circuit 130 converts the light energy received by the light energy plate 110 to the electrical energy and provides electrical energy for the thermoelectric cooling element 120 to allow the thermoelectric cooling element 120 to control the temperature of the indoor space.

To make persons having ordinary skill in the art understand and carry out the invention, an embodiment is taken to illustrate the invention hereinbelow. The persons having ordinary skill in the art should know that the following embodiment is an example, and the temperature control system of the invention can be combined or modified without departing from the spirit of the invention to achieve the needed efficiency.

FIG. 2 is a schematic diagram showing a temperature control system which is applied to adjust the temperature of closed space according to one embodiment of the invention. As shown in FIG. 1 and FIG. 2, the temperature control system 100 of the embodiment of the invention can be used to control temperature of indoor space 200. The temperature control system 100 further includes a shielding cover 140 in addition to the light energy plate 110, the thermoelectric cooling element 120 and the control circuit 130. The light energy plate 110 is provided at the top of the indoor space 200. In the embodiment, the number of the light energy plates 110 is, for example, two, the two light energy plates 100 are oblique toward two sides of the indoor space 200, and a gap 112 is formed between the two light energy plates 110. A plurality of small-sized light energy plates 110 can also be connected in a parallel or series connection mode according to an actual requirement. The light energy received by the light energy plate 110 of the embodiment may be solar light energy which includes the energy of visible light and invisible light such as infrared light, ultraviolet light, etc.

From the above, the thermoelectric cooling element 120 is provided under the light energy plate 110 and is located in the indoor space 200. In the embodiment, the thermoelectric cooling element 120 is formed by, for example, a plurality of thermoelectric cooling chips which are connected in a parallel connection mode, and it is electrically connected to the light energy plate 110. The hot side 122 of the thermoelectric cooling element 120 can directly contact the light energy plate 110, and the cold side 124 of the thermoelectric cooling element 120 faces the interior of the indoor space 200. The light energy plate 110 is mostly made of semiconductor. When photons collide with the surface of the light energy plate 110, electron diffusion occurs at joining surfaces of P-type and N-type semiconductors, and then current is conducted by metal conductors at a top end and a bottom end. The light energy plate 110 of the embodiment of the invention can recycle the heat energy of the hot side 122 and utilize the recycled heat energy to excite the energy level of the light energy plate 110, and therefore, the efficiency of converting the light energy to the electrical energy of the light energy plate 110 increases. Since the efficiency of converting the light energy to the electrical energy of the light energy plate 110 increases, the cold side 124 of the thermoelectric cooling element can provide a preferred cooling effect.

The control circuit 130 is electrically connected to the light energy plate 110 and the thermoelectric cooling element 120, and it can be provided inside or outside the indoor space 200 according to a requirement of a user. The control circuit 130 of the embodiment consists of, for example, a converter 132 and a controller 134, and the converter 132 is a direct current converter to enable the electrical energy which is converted from the light energy received by the light energy plate 110 to be steadily provided for the thermoelectric cooling element 120. The controller 134 is electrically connected to the converter 132 to control the electrical energy provided for the thermoelectric cooling element 120 by the converter 132. The controller 134 further includes a temperature sensor 134a, and the temperature sensor 134a may be provided in the indoor space 200 to sense the temperature of the indoor space 200 and transmit a temperature signal generated by sensed temperature to the controller 134. Thus, the controller 134 may control the temperature of the indoor space 200 in real time.

The shielding cover 140 is located above the gap 112, and it is suitable to shield the gap 112. The shielding cover 140 is used for preventing rainwater from entering the indoor space from the gap 112. In the embodiment, a distance is formed between the shielding cover 140 and the top of the light energy plate 110, and a heat removal system (not shown) may be provided at the gap 112. The heat removal system may be independently electrically connected to the thermoelectric cooling element 120 to enable two surfaces 122 and 124 of the thermoelectric cooling element 120 to have a predetermined temperature difference, and the temperature of the two surfaces 122 and 124 can increase or decrease, synchronously between the predetermined temperature. The heat removal system can further be electrically connected to the thermoelectric cooling element 120 and the controller 130 at the same time, and therefore, the controller 130 can control the heat removal system to rapidly dissipate heat and allow the temperature of the cold side of the thermoelectric cooling element 120 to decrease, thereby decreasing the temperature of the indoor space 200.

When indoor persons feel uncomfortable because of the high temperature of the indoor space 200, they can start the temperature control system 100 and set appropriate indoor temperature by themselves, and then the temperature control system 100 begins to control the temperature of the indoor space 200. In detail, after the temperature control system 100 of the embodiment is started, the light energy plate 110 receives light energy, converts the light energy to electrical energy and transmits the electrical energy to the control circuit 130. At the same time, the temperature sensor 134a senses the indoor temperature and transmits a sensed indoor temperature signal to the controller 134. After the controller 134 receives the temperature signal from the temperature sensor 134a, it adjusts the electrical energy provided for the thermoelectric cooling element 120 by the converter 132 according to the temperature difference between the indoor temperature and the predetermined temperature. In the embodiment, the electrical energy provided for the thermoelectric cooling element 120 by the converter 132 includes a voltage or a current, and each voltage or current inputted into the thermoelectric cooling element 120 is corresponding to one temperature difference between the temperature of the hot side 122 and that of the cold side 124 of the thermoelectric cooling element 120, respectively.

When a temperature difference between the indoor temperature sensed by the temperature sensor 134a and the predetermined temperature always exists, the electrical energy provided for the thermoelectric cooling element 120 by the control circuit 130 continuously changes along with the temperature difference between the indoor temperature and the predetermined temperature. Then, the temperature of the cold side 124 and the hot side 122 continuously change along with the electrical energy, and the control system 100 can adjust the indoor temperature.

Users may set the control circuit 130 to provide electrical energy for the thermoelectric cooling element 120 until the temperature sensed by the temperature sensor 134a is the same with the predetermined temperature, that is, the temperature difference between the sensed temperature and the predetermined temperature is zero. At that moment, the temperature control system 100 can be automatically shut down, and the light energy received by the light energy plate 110 is not converted to electrical energy or is converted to electrical energy to store. If the user wants to make the indoor space have constant temperature, he can set the temperature control system 100 not to automatically shut down to allow the light energy plate 110 to continue providing electrical energy to enable the temperature control system 100 to work.

To avoid the condition that the temperature control system 100 is incapable of being operated because of weak light causing the electrical energy to be insufficient, or to avoid the condition that no sufficient electrical energy is provided for the temperature control system 100 to adjust the indoor temperature because of insufficient light at night, users can install a storage battery 300 (as shown in FIG. 3) outside the temperature control system 100, and the storage battery 300 is electrically connected to the converter 132 in the control circuit 130 to store the electrical energy outputted by the light energy plate 110. The storage battery 300 can store electrical energy. When the light is weak at night or during the day, the storage battery 300 can provide the stored electrical energy for the temperature control system 100 to allow the temperature control system 100 to work.

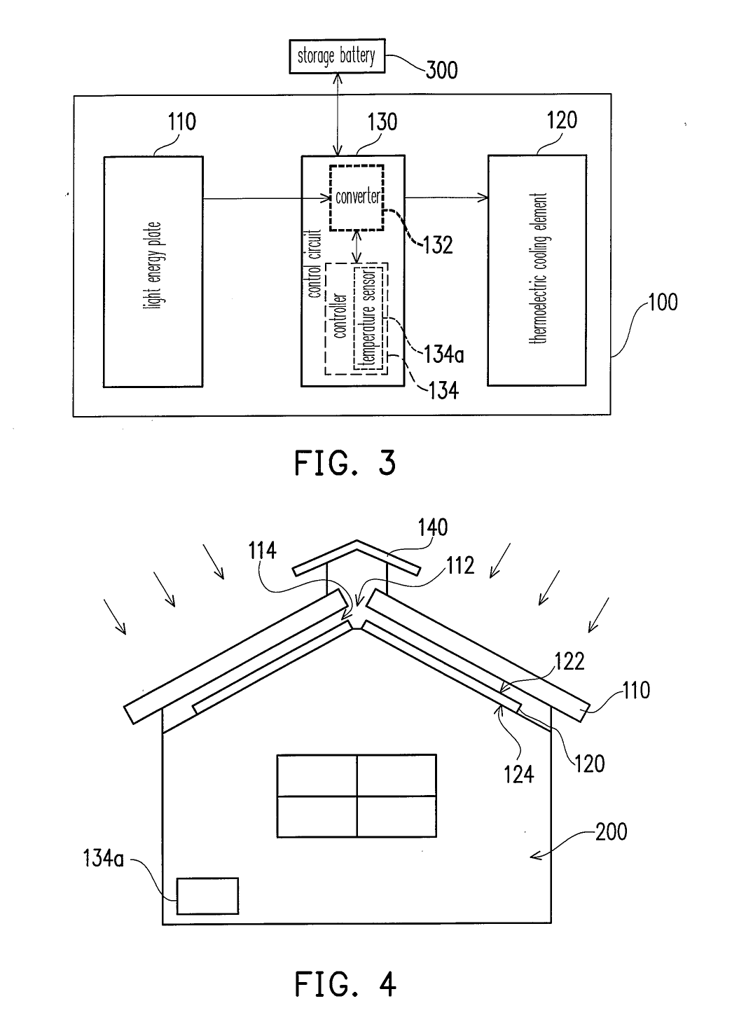

To allow the thermoelectric cooling element 120 to have preferred heat dissipation effect, a gap 114 may be formed between the thermoelectric cooling element 120 and the light energy plate 110 to be an airflow path, and the gap 114 communicates with the gap 112 to dissipate heat to enable the temperature control system 100 to rapidly adjust the indoor temperature to the predetermined temperature. FIG. 4 is a schematic diagram showing that an airflow path is formed between the thermoelectric cooling element and the light energy plate. As shown in FIG. 4, in detail, when the cold side 124 of the thermoelectric cooling element 120 conducts heat to the hot side 122, the hot side 122 can further conduct the heat to the air around the hot side 122, and at that moment, the air close to the hot side 122 is heated. Since the hot air is very light, the hot air can rise along the gap 114 and is exhausted from the gap 112, and then a heat removal system where convection is free is formed. To enhance the heat removal effect, the heat removal system can be disposed at the gap 114. Therefore, the heat can be rapidly removed, the thermoelectric cooling element 120 can have preferred heat dissipation effect, and the temperature control system 100 can rapidly adjust the indoor temperature to the predetermined temperature.

From the above embodiments, the heat generated by the hot side 124 of the thermoelectric cooling element 120 can be utilized to excite the energy level of the light energy plate 110. Since the energy level of electrons rises when the light energy plate 110 is heated, the efficiency of converting the light energy to electrical energy of the light energy plate 110 increases. The temperature control system 100 uses renewable energy as an electricity source via the photoelectric conversion structure formed by the light energy plate 110, the thermoelectric cooling element 120 and the control circuit 130, and no derivative or waste is discharged during a power generation process, thereby protecting the environment.

To sum up, the temperature control system 100 of the invention uses the renewable energy as the electricity source, and no derivative or waste is discharged during a power generation process and a temperature control process, thereby protecting the environment. Further, the heat generated by the hot side of the thermoelectric cooling element is used to excite the energy level of the light energy plate, and the energy level of the electrons increases for the light energy plate is heated, so that the objective of enhancing the efficiency of converting the light energy to the electrical energy of the light energy plate is achieved.

Although the present invention has been described in considerable detail with reference to certain preferred embodiments thereof, the disclosure is not for limiting the scope of the invention. Persons having ordinary skill in the art may make various modifications and changes without departing from the scope and spirit of the invention. Therefore, the scope of the appended claims should not be limited to the description of the preferred embodiments described above.

What is claimed is:

1. A photoelectric conversion structure comprising:
a light energy plate which is suitable to receive light energy and convert the light energy to electrical energy;
a thermoelectric cooling element having a hot side and a cold side, wherein the hot side faces the light energy plate; and
a control circuit electrically connected to the light energy plate and the thermoelectric cooling element, wherein the control circuit is suitable to provide the electrical energy for the thermoelectric cooling element.

2. The photoelectric conversion structure according to claim 1, wherein the light energy plate is a solar energy plate.

3. The photoelectric conversion structure according to claim 1, wherein the light energy is visible ray or invisible ray.

4. The photoelectric conversion structure according to claim 1, wherein the control circuit comprises a converter and a controller, the converter is electrically connected to the light energy plate and the thermoelectric cooling element, and the controller is electrically connected to the converter.

5. The photoelectric conversion structure according to claim 4, wherein the controller further comprises a temperature sensor which is suitable to transmit a temperature signal sensed by the temperature sensor to the controller.

6. The photoelectric conversion structure according to claim 1, wherein the hot side directly contacts the light energy plate.

7. A temperature control system which is suitable to adjust the temperature of closed space, the temperature control system comprising:
a light energy plate which is suitable to receive light energy and convert the light energy to electrical energy;
a thermoelectric cooling element having a hot side and a cold side, wherein the hot side faces the light energy plate, and the cold side faces the interior of the closed space; and
a control circuit electrically connected to the light energy plate and the thermoelectric cooling element, wherein the control circuit is suitable to provide the electrical energy for the thermoelectric cooling element and control the temperature of the interior of the closed space.

8. The temperature control system according to claim 7, wherein the control circuit comprises a converter and a controller, the converter is electrically connected to the controller, the controller further comprises a temperature sensor disposed in the closed space, and the temperature sensor is suitable to transmit a temperature signal sensed by the temperature sensor to the controller.

9. The temperature control system according to claim 7 further comprising a storage battery electrically connected to the light energy plate and the control circuit.

10. The temperature control system according to claim 7 further comprising a heat removal system electrically connected to the thermoelectric cooling element.

11. The temperature control system according to claim 7, wherein the hot side directly contacts the heat energy plate.

12. A temperature control system applied to closed space, the temperature control system comprising:
two light energy plates obliquely provided at the top of the closed space, wherein a first gap is formed between the two light energy plates, and the two light energy plates are suitable to receive light energy and convert the light energy to electrical energy;
at least a thermoelectric cooling element provided in the closed space and electrically connected to the two light energy plates, wherein the thermoelectric cooling element has a hot side and a cold side, the hot side faces the light energy plate, and the cold side faces the interior of the closed space;
a control circuit electrically connected to the two light energy plates and the thermoelectric cooling element, wherein the control circuit is suitable to provide the electrical energy for the thermoelectric cooling element to control the temperature of the interior of the closed space; and
a shielding cover which is located above the first gap between the two light energy plates and is suitable to shield the first gap, wherein a distance is formed between the shielding cover and tops of the two light energy plates.

13. The temperature control system according to claim 12, wherein the light energy plate is a solar energy plate.

14. The temperature control system according to claim 12, wherein a second gap is formed between the hot side of the thermoelectric cooling element and the light energy plates.

15. The temperature control system according to claim 14 further comprising a heat removal system provided at the second gap and electrically connected to the thermoelectric cooling element.

16. The temperature control system according to claim 12 further comprising a storage battery electrically connected to the light energy plate and the control circuit.

17. The temperature control system according to claim 12, wherein the control circuit comprises a converter and a controller, and the converter is electrically connected to the controller.

18. The temperature control system according to claim 17, wherein the controller further comprises a temperature sensor which is suitable to transmit a temperature signal sensed by the temperature sensor to the controller.

19. The temperature control system according to claim 18, wherein the temperature sensor is disposed in the closed space.

20. The temperature control system according to claim 12, wherein the hot side directly contacts the light energy plate.
